(19) United States
(12) Patent Application Publication
(10) Pub. No.: US 2022/0320001 A1
(43) Pub. Date: Oct. 6, 2022

(54) A MASK LAYOUT METHOD, A MASK LAYOUT DEVICE, AND A MASK

(71) Applicant: CHANGXIN MEMORY TECHNOLOGIES, INC., Hefei, Anhui (CN)

(72) Inventor: Jing LI, Hefei (CN)

(73) Assignee: CHANGXIN MEMORY TECHNOLOGIES, INC., Hefei, Anhui (CN)

(21) Appl. No.: 17/310,664

(22) PCT Filed: Mar. 24, 2021
(86) PCT No.: PCT/CN2021/082795

§ 371 Date: Aug. 16, 2021

(30) Foreign Application Priority Data
Apr. 13, 2020 (CN) 202010287352.5

(51) Int. Cl. H01L 23/544

(52) U.S. Cl. CPC H01L 23/544; H01L 2223/54426; H01L 2223/5446

(57) ABSTRACT

A mask layout method includes: forming, on a mask, chip patterns arranged in an array, a scribe line being formed between every two adjacent chip patterns, the scribe line being used to provide mark patterns thereon, the mark patterns comprising at least first mark patterns; acquiring a set number of divided units of the first mark patterns; providing the set number of divided units in sequence on the scribe line so that the first mark patterns do not cover other mark patterns; and providing, on the scribe line, first mark pattern elements to replace at least two adjacent divided units, the first mark pattern elements completely overlapping patterns formed by the at least two adjacent divided units.

### CROSS-REFERENCE TO RELATED APPLICATIONS

The present disclosure claims priority to Chinese Patent Application No. 202010287352.5, entitled “a mask layout method, a mask layout device and a mask”, filed on Apr. 13, 2020, which is incorporated herein by reference in its entirety.

### TECHNICAL FIELD

The present disclosure relates to the field of semiconductor layout, and in particular to a mask layout method, a mask layout device and a mask.

### BACKGROUND

In the semiconductor manufacturing process, the photolithography process is the most important circuit pattern transfer process. The mask, as an important material for realizing the photolithography process, may be used to fabricate the circuit layout of a semiconductor chip. In the semiconductor processing mode, first, the IC design company designs a wafer circuit diagram; and the photomask company designs the mask frame data, and merges the wafer circuit diagram and the mask frame data to form a mask.

The mask frame data generally comprises marks of various processes and electrical parameters related to the production process. According to the required masks and the chip size, the size of various masks may be calculated; and the masks that need to be split are manually divided into multiple mark elements with different lengths, and then manually arranged and set. The splitting and layout process makes the entire manual layout process cumbersome and complicated, resulting in a huge waste of labor costs. Moreover, the layout structure is not highly optimized, and has the disadvantages of instability and inaccuracy.

### SUMMARY

Embodiments of the present disclosure provide a mask layout method, a mask layout device and a mask, to solve the problem of low efficiency and poor accuracy in manual layout of masks.

According to an aspect of the present disclosure, an embodiment of the present disclosure provides a mask layout method, comprising:

forming, on a mask, chip patterns arranged in an array, a scribe line being formed between every two adjacent chip patterns, the scribe line being used to provide mark patterns thereon, the mark patterns comprising at least first mark patterns;

acquiring a set number of divided units of the first mark patterns according to measurement alignment requirements of the first mark patterns;

providing the set number of divided units in sequence on the scribe line so that the first mark patterns do not cover other mark patterns; and

providing, on the scribe line, first mark pattern elements to replace at least two adjacent divided units, the first mark pattern elements completely overlapping patterns formed by the at least two adjacent divided units.

According to another aspect of the present disclosure, an embodiment of the present disclosure provides a mask layout device, comprising:

a chip pattern layout module, configured to form, on a mask, chip patterns arranged in an array, a scribe line being formed between every two adjacent chip patterns, the scribe line being used to provide mark patterns thereon, the mark patterns comprising at least first mark patterns;

a number acquisition module, configured to acquire a set number of divided units of first mark patterns according to measurement alignment requirements of the first mark patterns;

an automatic layout module, configured to provide the set number of divided units in sequence on the scribe line so that the first mark patterns do not cover other mark patterns; and

an element replacement module, configured to provide, on the scribe line, first mark pattern elements to replace at least two adjacent divided units, the first mark pattern elements completely overlapping patterns formed by the at least two adjacent divided units.

According to yet another aspect of the present disclosure, an embodiment of the present disclosure further provides a mask, laid out by the mask layout method described in any embodiment of the present disclosure, comprising: chip patterns arranged in an array, a scribe line being formed between every two adjacent chip patterns, the scribe line being used to provide mark patterns thereon, the mark patterns comprising at least first mark patterns.

In the present disclosure, when the mask is laid out, it is necessary to provide mark patterns on a scribe line between adjacent chip patterns in an array of chip patterns to meet the alignment and measurement requirements of the photolithography process. For first mark patterns with a large total length, they may be divided into divided units with a small length. The number of divided units to be provided on a scribe line may be determined, according to the measurement and alignment requirements of the first mark patterns set by the user. All the divided units are automatically provided on the scribe line in sequence, in such a manner that the divided units will not affect the placement of other mark patterns. The divided units may be provided separately, or multiple divided units may be provided adjacent to each other. In the embodiments, at least two adjacent divided units may be replaced by corresponding first mark pattern elements. Moreover, the first mark pattern elements have the same size as patterns formed by the at least two adjacent divided units. In this way, the layout of the first mark patterns is completed. In the embodiments of the present disclosure, first mark pattern elements with different lengths are formed by stacking a different number of divided units, so that the first mark pattern elements may be filled in gaps between other mark patterns. In this way, the failure in placement of manually split first mark pattern elements into the gaps is avoided, and various mark patterns can be optimally placed on the scribe line. The space utilization of the scribe line is improved, the problem of time-consuming manual placement is solved, and the placement accuracy is improved.

### BRIEF DESCRIPTION OF THE DRAWINGS

The above-mentioned and other features and advantages of the present invention will become more apparent by describing in detail the exemplary implementations of the present invention with reference to the accompanying drawings.

FIG. 1 is a schematic flowchart of a mask layout method according to an embodiment of the present disclosure;

FIG. 2 is a structure diagram of a mask according to an embodiment of the present disclosure;

FIG. 3 is a partial structure diagram of the mask according to the embodiment of the present disclosure;

FIG. 4 is a structure diagram of another mask according to an embodiment of the present disclosure;

FIG. 5 is a schematic flowchart of another mask layout method according to an embodiment of the present disclosure;

FIG. 6 is a schematic flowchart of another mask layout method according to an embodiment of the present disclosure;

FIG. 7 is a schematic flowchart of another mask layout method according to an embodiment of the present disclosure; and

FIG. 8 is a structure diagram of a mask layout device according to an embodiment of the present disclosure.

### DETAILED DESCRIPTION

The present disclosure will be further described below with reference to the accompanying drawings by embodiments. It may be understood that the specific embodiments to be described herein are only used to explain the present disclosure, rather than limiting the present disclosure. In addition, it should be noted that, for ease of description, only a part of the structure related to the present disclosure is shown in the accompanying drawings instead of all of the structure.

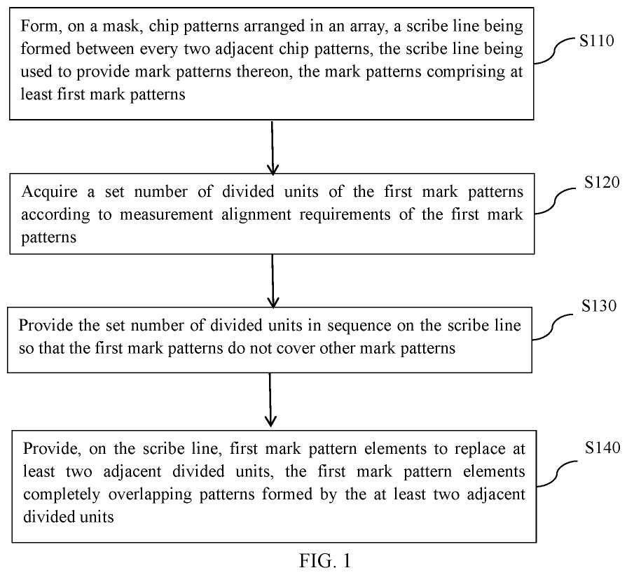

FIG. 1 is a schematic flowchart of a mask layout method according to an embodiment of the present disclosure. An embodiment of the present disclosure provides a mask layout method for implementing the automatic layout of various patterns, especially first mark patterns to be split, of the mask by a layout device. As shown in FIG. 1, the mask layout method in this embodiment comprises the following steps.

S110: Chip patterns arranged in an array are formed on a mask, a scribe line being formed between every two adjacent chip patterns, the scribe line being used to provide mark patterns thereon, the mark patterns comprising at least first mark patterns.

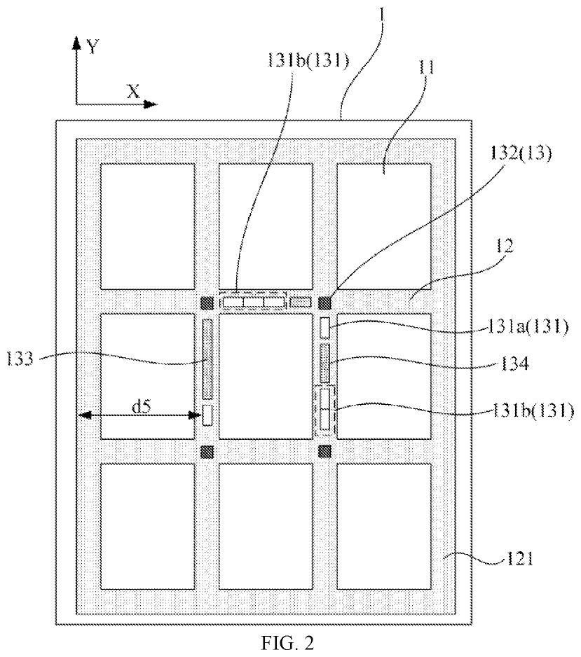

FIG. 2 is a structure diagram of a mask according to an embodiment of the present disclosure. Chip patterns 11 arranged in an array are formed on a mask 1. The chip patterns 11 correspond to the positions of the chips on the wafer in the actual photolithography process, and the array of chip patterns formed by multiple chip patterns corresponds to the array of chips on the wafer. And, the chip pattern 11 has the same size as the corresponding chip. A scribe line 12 is formed between every two adjacent chip patterns 11. In an embodiment, as shown in FIG. 2, a circle of scribe lines 12 is provided around the entire array of chip patterns. The scribe line 12 forms the frame of the mask. A large master mask may be scribed along the scribe line 12 to form the mask shown in FIG. 2. For example, the array of 3*3 chip patterns shown in FIG. 2 is formed by scribing a master mask including an array of N*N chip patterns along the scribe line 12, where N is an integer greater than 2. FIG. 2 shows an array of 3*3 chip patterns. In this example, the array of chip patterns may be an array of 4*3 or 2*6 chip patterns. The number of chip patterns 11 in an array is not limited in this embodiment.

In order to achieve the subsequent alignment between the mask and the wafer, or to the alignment between the mask and the exposure machine, or to leave an alignment mark on the wafer to achieve the alignment between the various film layers formed on the wafer, mark patterns may be formed on the scribe line 12.

S120: A set number of divided units of first mark patterns is acquired according to measurement alignment requirements of the first mark patterns.

Still referring to FIG. 2, in this embodiment, the mark patterns 13 comprise at least first mark patterns 131. In this embodiment, the set total length of the first mark patterns 131 on the entire mask is relatively large. Exemplarily, the set total length of the first mark patterns is 28790 μm. Therefore, during the layout of the first mark patterns 131, in the related art, it is often to divide the first mark patterns 131 into first mark pattern elements by means of manual layout, and set them at different positions of the scribe line 12. Specifically, as shown in FIG. 2, the first mark pattern elements are separately provided in different scribe lines 12 in a first direction X and a second direction Y. Because the mark patterns 13 comprise a variety of mark patterns, some mark patterns need to be provided at a fixed position. In order to adapt to the placement rules of other mark patterns, the first mark patterns 131 need to be divided to first mark pattern elements with different lengths. However, errors often occur during manual division. For example, the first mark pattern elements may be too long, so that other mark patterns cannot be placed in the scribe line 12 at the corresponding position. Moreover, the manual layout process is cumbersome and complicated, resulting in a huge waste of labor costs. It should be noted that the length of the first mark pattern elements in this embodiment is the length thereof in the extension direction of the scribe line because, in the width direction of the scribe line, the width of each first mark pattern element is constant. Only the size and length of the first mark patterns in the extension direction of the scribe line are limited in this embodiment.

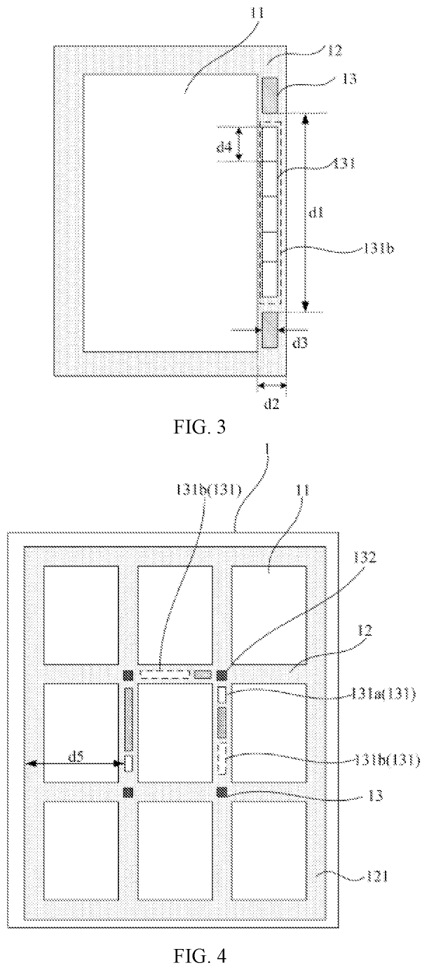

In this embodiment, referring to FIG. 2, the first mark patterns 131 may be divided into smaller divided units 131a, and many divided units 131a are stacked one by one to form the shape of first mark pattern elements with a desired length, exemplarily, as shown in FIG. 3 which is a partial structure diagram of the mask according to the embodiment of the present disclosure. If the length of a gap formed between two other types of mark patterns 13 is d1, only five divided units 131a can be placed in the gap and the sixth divided unit 131a cannot be placed in the gap. Compared with the manual placement method, if the length of the manually split first mark pattern element is greater than dl, the first mark pattern elements cannot be placed in the gap and the first mark pattern elements need to be reset. The operation process is very complicated. In contrast, in this example, if the sixth divided unit 131a cannot be placed in the gap, a pattern formed by five divided units 131a is placed in the gap as the first mark pattern element 13 lb. No rework is required, which improves the layout efficiency.

Still referring to FIG. 3, the width d2 of the scribe line 12 may be less than or equal to 80 μm; the width d3 of the first mark patterns 131 or the divided unit 131a is less than or equal to 60 μm; and the length of each divided unit 131a ranges from 40 μm to 500 μm. In this embodiment, the width d3 of the first mark patterns 131 or the divided unit 131a is less than the width d2 of the scribe line 12. In this embodiment, if the width d2 of the scribe line 12 may be less than or equal to 60 μm, the width d3 of the divided unit 131a may be less than or equal to 45 μm, and the length d4 of each divided unit 131a may range from 40 μm to 500 μm.

In this embodiment, a variety of divided units 131a with different lengths may be provided to meet different layout requirements. For example, divided units 131a with a length of 180 μm and 436 μm may be provided. If divided units 131a with a length of 436 μm cannot be placed in the space on the current scribe line, divided units 131a with a length of 180 μm can be placed in the space. By the provision of a variety of different divided units 131a, more diverse divided units 131a can be implemented, which is convenient for realizing an optimal layout.

The divided units 131a are the same in length. By unifying the specification of the divided units 131a, during the placement of the divided units 131a, the length of the first mark pattern elements 131b may be determined intuitively by the number of the placed divided units 131a. The layout algorithm and layout process of the divided units 131a is further simplified. Specifically, in this embodiment, the value obtained by dividing the set total length of the first mark patterns 131 by the length d4 of the divided unit 131a is the set number of the divided units 131a.

S130: A set number of divided units are provided in sequence on the scribe line so that the first mark patterns do not cover other mark patterns.

Still referring to FIG. 2, in this embodiment, the divided units 131a may be arranged according to the positions of other mark patterns on the scribe line 12, and the set number of the divided units 131a are all provided or filled at the empty positions of the scribe line 12. The layout device may be used to compare the size of the space on the scribe line 12 with the length of the divided units 131a, to automatically lay out first mark pattern elements 131b with different lengths, so that the first mark patterns 131 do not cover other mark patterns 13.

The first mark patterns 131 are film layer alignment mark patterns. The other mark patterns comprise at least one of the following: electrical measurement mark patterns, mask quality measurement mark patterns, and mask alignment mark patterns. In order to enhance the accuracy of a film layer finally formed on the wafer, the first mark patterns 131 may be set as film layer alignment mark patterns, so that the discretely arranged divided units 131a can effectively mark the position of the film layer in multiple directions. The fabrication yield of chips is improved. In addition, the other mark patterns may comprise electrical measurement mark patterns, mask quality measurement mark patterns, and mask alignment mark patterns, to improve the accuracy of the photolithography process. The other mark patterns in this embodiment may comprise other types of mark patterns. The specific mark pattern type of the other mark patterns is not limited in this embodiment.

Still referring to FIG. 2, providing the set number of divided units 131a in sequence on the scribe line 12 may comprise: providing the set number of divided units 131a in sequence on the scribe line 12 according to a preset position setting rule for divided units; wherein the preset position setting rule for divided units may be that the divided units are provided on an inner side of an outer scribe line 121 in an array of chip patterns, and the distance d5 between the divided units 131a and the outer scribe line 121 is greater than or equal to a set threshold, the set threshold being greater than or equal to 3000 μm. A position setting rule may be provided for each mark pattern type. In this embodiment, the preset position setting rule for divided units may be that the divided units are provided on an inner side of an array of chip patterns, and the distance to an outer scribe line 121 exceeds the set threshold. The divided units 131a may be provided in the center of an array of chip patterns. This is not limited in this embodiment. During the automatic layout of the divided units 131a, on the premise that the first mark patterns 131 do not cover other mark patterns 13, the divided units 131a are placed according to the position setting rule for divided units, to thus automatically achieve the optimal layout of the first mark patterns 131.

S140: First mark pattern elements are provided on the scribe line to replace at least two adjacent divided units, the first mark pattern elements completely overlapping patterns formed by the at least two adjacent divided units.

FIG. 4 is a structure diagram of another mask according to an embodiment of the present disclosure. After the layout of all the divided units 131a is completed, a plurality of adjacent divided units 131a may be spliced to form the shape of first mark pattern elements 131b, and the first mark pattern elements 131b may be provided, as a whole, to replace the adjacent divided units 131a. In the actual manufacturing process after the layout is completed, the first mark patterns 131 may be manufactured in unit of the first mark pattern elements 13 lb, instead of manufacturing a plurality of divided units 131a to finally form the first mark pattern elements 131b. The efficiency of the mask manufacturing process is improved. In this embodiment, the first mark pattern elements 131b are provided to replace the plurality of adjacent divided units 131b covered by the first mark pattern elements 13 lb. Eventually, the automatic division of the first mark patterns 131 into first mark pattern elements 131b with different lengths is realized. Therefore, the layout efficiency and accuracy of the first mark patterns 131 are improved.

In this embodiment of the present disclosure, when the mask is laid out, it is necessary to provide mark patterns on a scribe line between adjacent chip patterns in an array of chip patterns to meet the alignment and measurement requirements of the photolithography process. For first mark patterns with a large total length, they may be divided into divided units with a small length. The number of divided units to be provided on a scribe line may be determined, according to the measurement and alignment requirements of the first mark patterns set by the user. All the divided units are automatically provided on the scribe line in sequence, in such a manner that the divided units will not affect the placement of other mark patterns. The divided units may be provided separately, or multiple divided units may be provided adjacent to each other. In the embodiments, at least two adjacent divided units may be replaced by a corresponding first mark pattern element. Moreover, the first mark pattern elements have the same size as patterns formed by the at least two adjacent divided units. In this way, the layout of the first mark patterns is completed. In this embodiment of the present disclosure, first mark pattern elements with different lengths are formed by stacking a different number of divided units, so that the first mark pattern elements may be filled in gaps between other mark patterns. In this way, the failure in placement of manually split first mark pattern elements into the gaps is avoided, and various mark patterns can be optimally placed on the scribe line. The space utilization of the scribe line is improved, the problem of time-consuming manual placement is solved, and the placement accuracy is improved.

On the basis of the above embodiments, in the step S130, when placing the first mark patterns and other mark patterns, each type of mark patterns has its own setting rules and positions. In this embodiment, the rules and positions are stored in the mask layout device as running scripts. When the mask layout device is run, the mark patterns are optimally laid out according to the corresponding setting rules and positions, so that the mark patterns do not overlap each other.

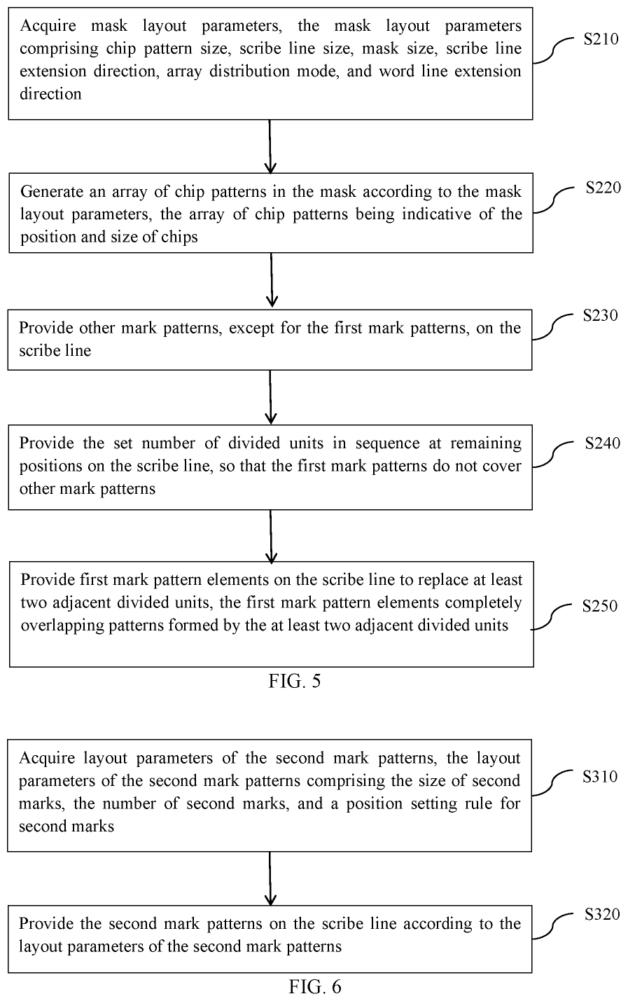

In another embodiment, forming chip patterns arranged in an array on the mask will be described in detail. Specifically, as shown in FIG. 5, which is a schematic flowchart of another mask layout method according to an embodiment of the present disclosure, the layout mask method in this embodiment comprises the following steps.

S210: Mask layout parameters are acquired, the mask layout parameters comprising chip pattern size, scribe line size, mask size, scribe line extension direction, array distribution mode, and word line extension direction.

S220: An array of chip patterns is generated in the mask according to the mask layout parameters, the array of chip patterns being indicative of the position and size of chips.

The above step S110 comprises the contents of steps S210 and S220 of this embodiment. In this embodiment, forming, on a mask, chip patterns arranged in an array specifically comprises: acquiring mask layout parameters input by the user. The mask layout parameters comprise: chip pattern size, i.e., the length and width of the chip patterns; scribe line size, i.e., the width of the scribe line; mask size, i.e., the length and width of the entire mask; scribe line extension direction, i.e., the arrangement direction of the array of chip patterns; word line extension direction; and array distribution mode, for example, arranged in a matrix, or arranged in a Chinese character “ [symbol] ” shape. According to the above parameters, the possibly largest chip patterns may be formed on the mask in a set direction at a set chip size.

S230: Other mark patterns, except for the first mark patterns, are provided on the scribe line.

S240: A set number of divided units are provided in sequence at remaining positions on the scribe line, so that the first mark patterns do not cover other mark patterns.

The above step S120 comprises the contents of steps S230 and S240 in this embodiment. In the processing of providing the set number of divided units in sequence at remaining positions on the scribe line so that the first mark patterns do not cover other mark patterns, since the first mark patterns are divided to a large number of divided units, then other mark patterns, except for the first mark patterns, may be provided first, and the divided units may be then filled in sequence at the remaining positions on the scribe line. In this way, the optimized division of the first mark patterns is realized.

S250: First mark pattern elements are provided on the scribe line to replace at least two adjacent divided units, the first mark pattern elements completely overlapping patterns formed by the at least two adjacent divided units.

In this embodiment, the array of chip patterns may be automatically laid out according to the layout parameters of the mask. And, before the first mark patterns are automatically laid out, other mark patterns are first laid out. Generally, the position of other mark patterns is relatively fixed. The optimized layout of the first mark patterns is implemented, on the premise of not hindering the placement of the other mark patterns, to effectively prevent the first mark patterns from occupying the setting positions of other mark patterns. The layout efficiency and accuracy are improved.

In an example of this embodiment, the step S230 will be further described in detail. FIG. 6 is a schematic flowchart of another mask layout method according to an embodiment of the present disclosure. In this example, the other mark patterns comprise second mark patterns. Providing other mark patterns, except for the first mark patterns, on the scribe line specifically comprises the following steps.

S310: Layout parameters of the second mark patterns are acquired, the layout parameters of the second mark patterns comprising the size of second marks, the number of second marks, and a position setting rule for second marks.

For each type of mark patterns, a fixed mark size and the number of marks may be determined according to user requirements. And, for each type of mark patterns, a corresponding position setting rule may be provided. Exemplarily, still referring to FIG. 2, the position setting rule for the second mark patterns 132 means that the second mark patterns are provided on four corners of the chip pattern 11. In addition, other position setting rules may be possible. It is not limited in this embodiment. In this embodiment, other mark patterns may comprise second mark patterns 132. Then, before laying out the first mark patterns 131, the second mark patterns 132 may be laid out according to the layout parameters of the second mark patterns.

S320: The second mark patterns are provided on the scribe line according to the layout parameters of the second mark patterns.

In this embodiment, before laying out the first mark patterns, other mark patterns need to be placed. The other mark patterns comprise second mark patterns. The second mark patterns may be provided on the scribe line according to the layout parameters of the second mark patterns. The accuracy of the automatic layout process is enhanced.

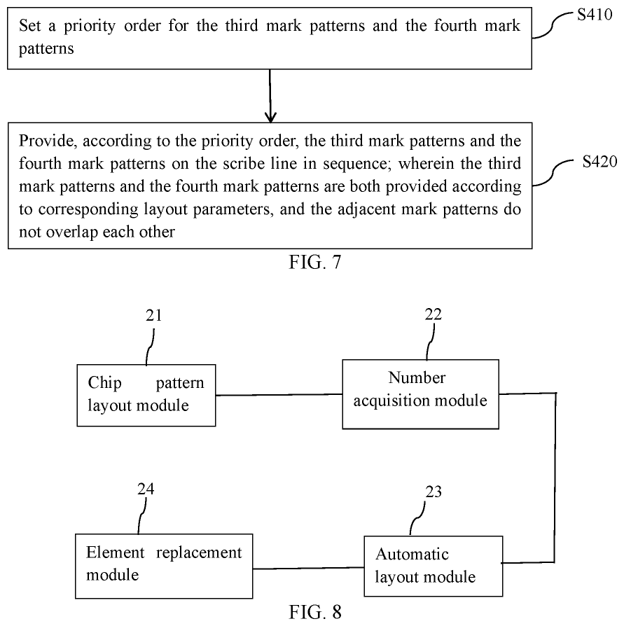

In another example of this embodiment, the step S230 will be further described in detail. FIG. 7 is a schematic flowchart of another mask layout method according to an embodiment of the present disclosure. In this example, the other mark patterns comprise third mark patterns and fourth mark patterns. Providing other mark patterns, except for the first mark patterns, on the scribe line specifically comprises the following steps.

S410: A priority order is set for the third mark patterns and the fourth mark patterns.

When the other mark patterns comprise a variety of types of mark patterns, a layout priority order may be set for the types of mark patterns in terms of importance; and mark patterns, which are important or which have a fixed position, are prioritized. Laying out the mark patterns according to the priority order further improves the automatic layout accuracy.

As shown in FIG. 2, in this embodiment, the other mark patterns comprise third mark patterns 133 and fourth mark patterns 134. In this embodiment, a priority order may be set for the third mark patterns 133 and the fourth mark patterns 134. Exemplarily, the fourth mark patterns 134 may be provided first, followed by the third mark patterns 133.

S420: According to the priority order, the third mark patterns and the fourth mark patterns are provided on the scribe line in sequence; wherein the third mark patterns and the fourth mark patterns are both provided according to corresponding layout parameters, and the adjacent mark patterns do not overlap each other.

Similarly, corresponding layout parameters may be set for each type of mark patterns. In the layout process of mark patterns type by type, each type of mark patterns may be laid out according to the corresponding layout parameters. The layout parameters of the third mark patterns comprise the size of third marks, the number of third marks, and a position setting rule for third marks, and the layout parameters of the fourth mark patterns comprise the size of fourth marks, the number of fourth marks, and a position setting rule for fourth marks.

In this embodiment, when laying out the other mark patterns except for the first mark patterns, a priority order is set for those types of mark patterns, and those types of mark patterns are laid out in sequence. This further improves the layout accuracy.

An embodiment of the present disclosure further provides a mask layout device. FIG. 8 is a structure diagram of a mask layout device according to an embodiment of the present disclosure. The mask layout device according to an embodiment of the present disclosure may be used to execute the mask layout method according to any embodiment of the present disclosure. As shown in FIG. 8, the mask layout device in this embodiment comprises:

a chip pattern layout module 21, configured to form, on a mask, chip patterns arranged in an array, a scribe line being formed between every two adjacent chip patterns, the scribe line being used to provide mark patterns thereon, the mark patterns comprising at least first mark patterns;

a number acquisition module 22, configured to acquire a set number of divided units of first mark patterns according to measurement alignment requirements of the first mark patterns;

an automatic layout module 23, configured to provide the set number of divided units in sequence on the scribe line so that the first mark patterns do not cover other mark patterns; and

an element replacement module 24, configured to provide, on the scribe line, first mark pattern elements to replace at least two adjacent divided units, the first mark pattern elements completely overlapping patterns formed by the at least two adjacent divided units.

In this embodiment of the present disclosure, when the mask is laid out, it is necessary to provide mark patterns on a scribe line between adjacent chip patterns in an array of chip patterns to meet the alignment and measurement requirements of the photolithography process. For first mark patterns with a large total length, it may be divided into divided units with a small length. The number of divided units to be provided on a scribe line may be determined, according to the measurement and alignment requirements of the first mark patterns set by the user. All the divided units are automatically provided on the scribe line in sequence, in such a manner that the divided units will not affect the placement of other mark patterns. The divided units may be provided separately, or multiple divided units may be provided adjacent to each other. In the embodiments, at least two adjacent divided units may be replaced by a corresponding first mark pattern element. Moreover, the first mark pattern elements have the same size as patterns formed by the at least two adjacent divided units. In this way, the layout of the first mark patterns is completed. In this embodiment of the present disclosure, first mark pattern elements with different lengths are formed by stacking a different number of divided units, so that the first mark pattern elements may be filled in gaps between other mark patterns. In this way, the failure in placement of manually split first mark pattern elements into the gaps is avoided, and various mark patterns can be optimally placed on the scribe line. The space utilization of the scribe line is improved, the problem of time-consuming manual placement is solved, and the placement accuracy is improved.

An embodiment of the present disclosure further provides a mask, laid out by the mask arrangement method described in any embodiment of the present disclosure, comprising: chip patterns 11 arranged in an array, a scribe line 12 being formed between every two adjacent chip patterns 11, the scribe line 12 being used to provide mark patterns 13 thereon, the mark patterns 13 comprising at least first mark patterns 131.

This embodiment comprises the technical features of the mask layout method according to any embodiment of the present disclosure, and has the technical effects of the mask layout method according to any embodiment of the present disclosure. In this embodiment, the layout of the first mark patterns on the mask can be optimized. The space utilization of the scribe line is improved, the instability of manually placing the first mark patterns is avoided, and the mask layout is highly reproducible, systematized and high in accuracy.

Note that the foregoing descriptions are only preferred embodiments of the present disclosure and the technical principles applied. It may be understood by those skilled in the art that the present disclosure is not limited to the specific embodiments described herein, and various apparent changes, adjustments and substitutions can be made without departing from the protection scope of the present disclosure. Therefore, although the present disclosure has been described in detail by the above embodiments, the present disclosure is not limited to those embodiments and can comprise more other equivalent embodiments without departing from the concept of the present disclosure. The scope of the present disclosure is defined the appended claims.

1. A mask layout method, comprising:
forming, on a mask, chip patterns arranged in an array, a scribe line being formed between every two adjacent chip patterns, the scribe line being used to provide mark patterns thereon, the mark patterns comprising at least first mark patterns;
acquiring a set number of divided units of the first mark patterns according to measurement alignment requirements of the first mark patterns;
providing the set number of divided units in sequence on the scribe line so that the first mark patterns do not cover other mark patterns; and
providing, on the scribe line, first mark pattern elements to replace at least two adjacent divided units, the first mark pattern elements completely overlapping patterns formed by the at least two adjacent divided units.

2. The mask layout method according to claim 1, wherein said forming, on a mask, chip patterns arranged in an array comprises:
acquiring mask layout parameters, the mask layout parameters comprising chip pattern size, scribe line size, scribe line extension direction, array distribution mode, and word line extension direction; and
generating an array of chip patterns in the mask according to the mask layout parameters, the array of chip patterns being indicative of the position and size of chips.

3. The mask layout method according to claim 1, wherein said providing the set number of divided units in sequence on the scribe line so that the first mark patterns do not cover other mark patterns comprises:
providing other mark patterns, except for the first mark patterns, on the scribe line; and
providing the set number of divided units in sequence at remaining positions on the scribe line, so that the first mark patterns do not cover other mark patterns.

4. The mask layout method according to claim 3, wherein the other mark patterns comprise second mark patterns; and
providing other mark patterns, except for the first mark patterns, on the scribe line comprises:
acquiring layout parameters of the second mark patterns, the layout parameters of the second mark patterns comprising the size of second marks, the number of second marks, and a position setting rule for second marks; and
providing the second mark patterns on the scribe line according to the layout parameters of the second mark patterns.

5. The mask layout method according to claim 3, wherein the other mark patterns comprise third mark patterns and fourth mark patterns; and
providing other mark patterns, except for the first mark patterns, on the scribe line comprises:
setting a priority order for the third mark patterns and the fourth mark patterns; and
providing, according to the priority order, the third mark patterns and the fourth mark patterns on the scribe line in sequence; wherein the third mark patterns and the fourth mark patterns are both provided according to corresponding layout parameters, and the adjacent mark patterns do not overlap each other.

6. The mask layout method according to claim 1, wherein said providing the set number of divided units in sequence on the scribe line comprises:
providing the set number of divided units in sequence on the scribe line according to a preset position setting rule for divided units; wherein the preset position setting rule for divided units is that the divided units are provided on an inner side of an outer scribe line in an array of chip patterns, and the distance between the divided units and the outer scribe line is greater than or equal to a set threshold, the set threshold being greater than or equal to 3000 μm.

7. The mask layout method according to claim 1, wherein a width of the scribe line is less than or equal to 80 μm; a width of the first mark patterns or the width of the divided unit are less than or equal to 60 μm; and
the length of each of the divided units ranges from 40 μm to 500 μm.

8. The mask layout method according to claim 1, wherein the first mark patterns are film layer alignment mark patterns; and
the other mark patterns comprise at least one of the following: electrical measurement mark patterns, mask quality measurement mark patterns, and mask alignment mark patterns.

9. A mask layout device, comprising:
a chip pattern layout module, configured to form, on a mask, chip patterns arranged in an array, a scribe line being formed between every two adjacent chip patterns, the scribe line being used to provide mark patterns thereon, the mark patterns comprising at least first mark patterns;
a number acquisition module, configured to acquire a set number of divided units of first mark patterns according to measurement alignment requirements of the first mark patterns;
an automatic layout module, configured to provide the set number of divided units in sequence on the scribe line so that the first mark patterns do not cover other mark patterns; and
an element replacement module, configured to provide, on the scribe line, first mark pattern elements to replace at least two adjacent divided units, the first mark pattern elements completely overlapping patterns formed by the at least two adjacent divided units.

10. A mask, laid out by the mask layout method according to claim 1, comprising:
chip patterns arranged in an array, a scribe line being formed between every two adjacent chip patterns, the scribe line being used to provide mark patterns thereon, the mark patterns comprising at least first mark patterns.

11. A mask, laid out by the mask layout method according to claim 2, comprising:
chip patterns arranged in an array, a scribe line being formed between every two adjacent chip patterns, the scribe line being used to provide mark patterns thereon, the mark patterns comprising at least first mark patterns.

12. A mask, laid out by the mask layout method according to claim 3, comprising:
chip patterns arranged in an array, a scribe line being formed between every two adjacent chip patterns, the scribe line being used to provide mark patterns thereon, the mark patterns comprising at least first mark patterns.

13. A mask, laid out by the mask layout method according to claim 4, comprising:
chip patterns arranged in an array, a scribe line being formed between every two adjacent chip patterns, the scribe line being used to provide mark patterns thereon, the mark patterns comprising at least first mark patterns.

14. A mask, laid out by the mask layout method according to claim 5, comprising:
chip patterns arranged in an array, a scribe line being formed between every two adjacent chip patterns, the scribe line being used to provide mark patterns thereon, the mark patterns comprising at least first mark patterns.

15. A mask, laid out by the mask layout method according to claim 6, comprising:
chip patterns arranged in an array, a scribe line being formed between every two adjacent chip patterns, the scribe line being used to provide mark patterns thereon, the mark patterns comprising at least first mark patterns.

16. A mask, laid out by the mask layout method according to claim 7, comprising:
chip patterns arranged in an array, a scribe line being formed between every two adjacent chip patterns, the scribe line being used to provide mark patterns thereon, the mark patterns comprising at least first mark patterns.

17. A mask, laid out by the mask layout method according to claim 8, comprising:
chip patterns arranged in an array, a scribe line being formed between every two adjacent chip patterns, the scribe line being used to provide mark patterns thereon, the mark patterns comprising at least first mark patterns.
